(19) United States
(12) Patent Application Publication
(10) Pub. No.: US 2005/0079711 A1
(43) Pub. Date: Apr. 14, 2005

(54) Hollow tip array with nanometer size openings and formation thereof

(75) Inventor: Heinz H. Busta, Park Ridge, IL (US)

Correspondence Address: STEVEN D WESEMAN, ASSOCIATE GENERAL COUNSEL, IP;CABOT MICROELECTRONICS CORPORATION, 870 NORTH COMMONS DRIVE, AURORA, IL, 60504, US

(73) Assignee: Cabot Microelectronics Corp.

(21) Appl. No.: 10/683,247

(22) Filed: Oct. 10, 2003

(51) Int. Cl. H01L 21/302; H01L 21/461

(52) U.S. Cl. 438/689; 438/690

(57) ABSTRACT

This invention provides tip assemblies and arrays of tip assemblies useful for nanoscale fluid delivery. The invention also provides methods of fabricating tip assemblies.

### BACKGROUND OF THE INVENTION

1. Field of the Invention

This invention relates to a tip assembly and an array of tip assemblies useful for nanoscale fluid delivery. The invention also relates to methods of fabricating tip assemblies and arrays thereof.

2. Description of the Related Art

The delivery of fluids using tip arrays is gaining popularity in various diversified fields such as healthcare (for example for administration of medications through the skin without agitating nerve endings), in diagnostics, and in nanolithography.

The tips in currently used tip arrays, such as those used in nanolithography, are solid. Uptake of a fluid into a solid tip generally requires dipping of the tip in a fluid source and then moving the tip to the substrate to which fluid is to be delivered. This process is analogous to writing with a quill pen.

One disadvantage of using the dipping method for fluid uptake is that only a limited amount of fluid can be taken up by the tip, thus limiting the amount of fluid deliverable to the substrate. Consequently, repeated dipping steps are necessary, especially for applications where larger amounts of fluid are required. This disadvantage is particularly relevant in nanolithography where the tip must be repositioned on the substrate after each redipping step. Such repeated repositioning can lead to errors and limit writing throughput.

Another disadvantage of the dipping method is that the flow of the liquid cannot be easily controlled. As with a quill pen, the amount of ink that is delivered to a substrate is greatest immediately after the dipping step, but diminishes during the delivery process, which can result in non-uniform amounts of fluid being delivered to the substrate.

A need exits, therefore, for new tips and tip arrays that overcome the above, and other disadvantages.

### BRIEF SUMMARY OF THE INVENTION

In one aspect, the invention provides a tip assembly for nanoscale fluid delivery, including delivery of liquids and gasses, comprising: a substrate; a fluid channel on the substrate; a shell layer enclosing the fluid channel; and a hollow tip in fluid communication with the fluid channel. In a preferred embodiment, the tip assembly comprises: a substrate; a cantilever positioned on the substrate and having a fluid channel; a hollow tip in fluid communication with the fluid channel and having an apical end for dispensing a fluid.

In another aspect, the invention provides a method for fabricating a tip assembly for nanoscale fluid delivery, said method comprising: forming on a substrate a cantilever supported on a first etchable layer; forming on the cantilever a fluid channel template and a tip template having a tip end; forming on the fluid channel template and the tip template a shell layer; removing the tip end, the fluid channel template and the tip template; and partially etching the first etchable layer.

### BRIEF DESCRIPTION OF THE DRAWINGS

FIG. 1. is a cross-sectional schematic view of a tip assembly 10 comprising a substrate 20 on which is positioned a cantilever 30 having a fluid channel 40.

FIG. 2(a) is a cross-sectional schematic view of a tip assembly including a substrate 20 on which has been deposited a first etchable layer 131 and a cantilever material.

FIG. 2(b) is a cross-sectional schematic view of a of a tip assembly including a fluid flow channel template 140 formed along the longitudinal axis of cantilever 30.

FIG. 2(c) is a cross-sectional schematic view of a tip assembly including a tip template 150 formed on cantilever 30 and fluid flow channel template 140.

FIG. 2(d) is a cross-sectional schematic view of a tip assembly including a shell layer.

FIG. 2(e) is a cross-sectional schematic view of a of a tip assembly including a tip support layer 52.

FIG. 2(f) is a cross-sectional schematic view of a tip assembly including a tip template 150 from which has been removed end 152 and any materials thereon.

FIG. 2(g) is a cross-sectional schematic view of a tip assembly from which tip template 150, fluid flow channel template 140, and first etchable layer 131 have been removed.

FIG. 3(a) is a cross-sectional schematic view of a tip assembly in which a CMP layer 160 deposited over shell layer 42, and covering end 152 of tip template 150.

FIG. 3(b) is a cross-sectional schematic view of a tip assembly in which the portion of CMP layer 160 covering end 152, and a portion of the apical end as well as materials deposited thereon, have been removed.

FIG. 3(c) is a cross-sectional schematic view of a tip assembly from which remaining CMP layer 160 has been removed.

### DETAILED DESCRIPTION OF THE PREFERRED EMBODIMENT

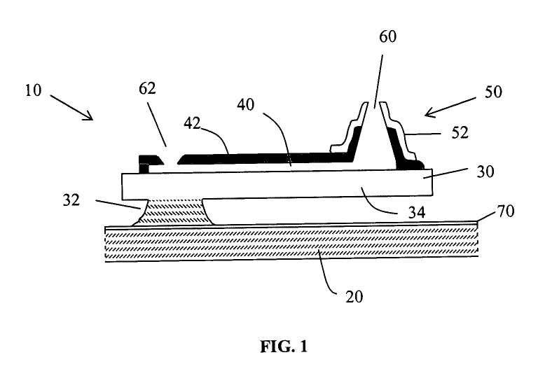

As noted above, in one aspect the invention provides a tip assembly for nanoscale fluid (liquid and/or gas) delivery. The tip assembly comprises: a substrate; a fluid channel on the substrate; a shell layer enclosing the fluid channel; and a hollow tip in fluid communication with the fluid channel. In a preferred embodiment of this aspect of the invention, the tip assembly comprises: a substrate; a cantilever or cantilever array positioned on the substrate each cantilever having a fluid channel; and a hollow tip in fluid communication with the fluid channel and having an apical end for dispensing a fluid. One embodiment of a tip assembly according to the invention is depicted in FIG. 1.

FIG. 1 shows a cross-sectional view of a tip assembly 10 according to the preferred embodiment. The tip assembly includes a substrate 20, a cantilever 30 having a fluid channel 40 positioned on the substrate 20, and a hollow tip 50 positioned on cantilever 30 and in fluid communication with fluid channel 40.

Substrate 20 is, for instance, single crystal silicon, polycrystalline silicon, alumina, a ceramic material, fused silica, quartz, or the like. Other substrate materials known in the art can be used. Electrical and/or mechanical features may be present in or on the substrate.

Cantilever 30 comprises an anchor portion 32 and an arm portion 34. Various cantilever dimensions can be used, depending in part on the final application for the tip assembly 10. As an example, the arm portion 34 of cantilever 30 can be between about 10 μm and 300 μm in length (along its longitudinal axis), about 5 μm and 30 μm in width, and about 0.1 μm and 5 μm in thickness. Arm portion 34 of cantilever 30 can be made from a variety of materials including, but not limited to, polycrystalline silicon (polysilicon), metals such as tantalum, and nitrides and carbides such as silicon nitride and silicon carbide. Preferred materials for arm portion 34 include silicon carbide, silicon nitride, or polysilicon.

Fluid channel 40 is located longitudinally along arm portion 34 of cantilever 30. A shell layer 42 forms the top and side walls of fluid channel 40. Shell layer 42 can be made of various materials, including, but not limited to, polycrystalline silicon, metals such as copper and tantalum, nitrides such as silicon nitride, and carbides such as silicon carbide, and other materials such as silicon dioxide, or polyimide. Preferred materials for shell layer 42 include polyimides. The dimensions of fluid channel 40 can vary depending in part on the final application for the tip assembly 10, and can be readily determined by a person of ordinary skill in the art.

Hollow tip 50 is positioned on cantilever 30 and is in fluid communication with fluid channel 40. Fluid is delivered into opening 62 (discussed below), through fluid channel 40, and out through the apical end 60 of hollow tip 50. The dimensions of hollow tip 50 vary depending in part on the final application for the tip assembly 10. As an example, hollow tip 50 can be between about 3 μm and 15 μm in inner diameter at its base, and between about 3 μm and 15 μm in height. The opening in apical end 60 can be, for example, about 5 nm to about 100 nm in diameter. Shell layer 42 forms the walls of hollow tip 50, as well as fluid channel 40, as noted above. Additional structural support for hollow tip 50 can be provided by an optional support layer 52. Optional support layer 52 can be made of various materials including, but not limited to, polycrystalline silicon, metals such as copper and tantalum, nitrides such as silicon nitride, and carbides such as silicon carbide, and other materials such as silicon dioxide, or polyimide, and is about 0.01 μm to about 1 μm in thickness. Preferably, optional support layer 52 is tantalum.

Fluid is supplied to fluid channel 40 by external valves and pumps through opening 62. Analog and/or digital circuitry can be included on the substrate (not shown) to control the valves and pumps. Circuitry can also be present for controlling the position of the tips and tip arrays for a given application. When electronic circuitry is present, it is preferred that such circuitry is protected from the fabrication process by optional protective layer 70. Protective layer 70 is preferably silicon carbide or silicon nitride and is preferably about 0.5 μm to about 3 μm in thickness.

Valves and pumps for use in microfluidic devices are well know in the art; see for example Unger et al., Science 288, 113 (2000). Circuitry for controlling valves and pumps is also well known in the art; see for example Thorsen et al., Science 298, 580 (2002).

In a preferred embodiment, a plurality of tip assemblies (i.e., 2 or more) are arranged as an array on a substrate. In this embodiment, each tip assembly comprises a cantilever positioned on the substrate and having a fluid channel; and a hollow tip in fluid communication with the fluid channel and having an apical end for dispensing a fluid. There is no particular minimum or maximum limit on the number of tip assemblies that comprise the tip array, and the number will generally depend on the final application.

In an alternative embodiment, two or more hollow tips are positioned on the same cantilever. In this embodiment, the tips can share a fluid channel or can each possess an independent flow channel positioned on the cantilever. In a further embodiment, multiple cantilever arms can share the same cantilever anchor 32.

Fluids that can be delivered by the tip assembly of the invention will depend on the particular fluid delivery application. Examples include, but are not limited to, pharmaceutical containing liquids, liquids containing DNA and/or proteins, acids, and gases.

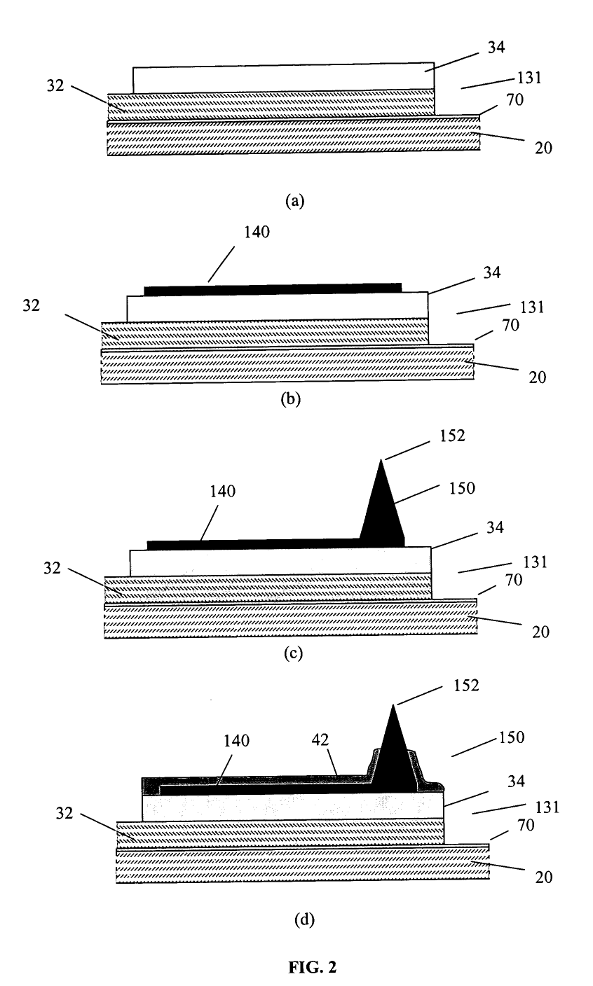

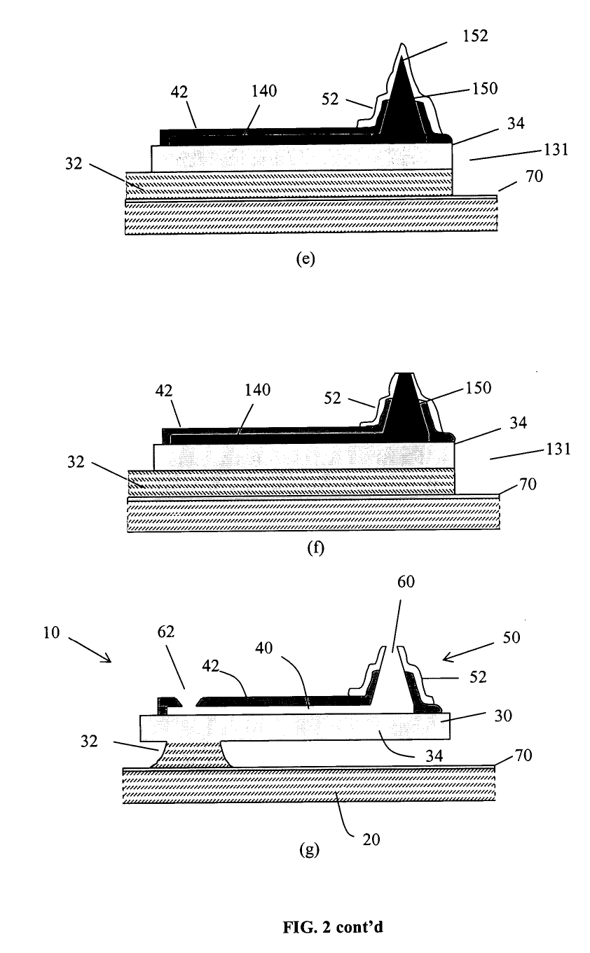

In a second aspect, the invention provides a method for fabricating a tip assembly for nanoscale fluid delivery. The method comprises: forming on a substrate a cantilever supported on a first etchable layer; forming on the cantilever a fluid channel template and a tip template having a tip end; forming on the fluid channel template and the tip template a shell layer; optionally forming on the tip template and tip end a support layer; removing the tip end, the fluid channel template and the tip template; and partially etching the first etchable layer. This aspect of the invention is schematically depicted in FIGS. 2(a)-2(g).

FIG. 2(a) is a cross-sectional view of a substrate 20 on which has been deposited a first etchable layer 131 and arm portion 34 of cantilever 30.

A protective layer 70 is optionally deposited and planarized by chemical mechanical planarization (CMP) on substrate 20, prior to the deposition of etchable layer 131. Protective layer 70, which is, for example, silicon nitride or silicon carbide, is preferably present when electronic circuitry or other sensitive structures are embedded in the substrate 20, and serves to protect such structures from corrosion during the fabrication process.

Etchable layer 131 can be made from various etchable materials including silicon dioxide, polyimide, metals such as aluminum and copper, polymethylmethacrylate (PMMA) and other plastics, other photoresist materials, and the like. Preferably, etchable layer 131 is silicon dioxide and is about 0.2 to about 10 μm in thickness.

Arm portion 34 of cantilever 30 is preferably a low stress and low stress gradient material such as, for example, polycrystalline silicon, silicon nitride, silicon carbide, or hydrogenated silicon carbide. Preferred materials include polycrystalline silicon and silicon nitride. Arm portion 34 is preferably about 0.1-5 μm thick. Arm portion 34 is photoshaped into the desired cantilever shape (photoshaping is discussed below).

Anchor portion 32 is formed during the subsequent etching of etchable layer 131, as discussed below. In particular, enough of the etchable layer 131 is etched during the subsequent etching step discussed below to release the cantilever, while still leaving an anchor for cantilever arm 34. Alternatively, cantilever anchor 32 can be formed by etching a cavity into etchable layer 131 prior to deposition of cantilever arm 34. The cavity is of the same dimensions and is at the same location that is necessary for the anchor potion 32. Deposition of the cantilever arm 34 material also includes deposition of the same arm material into the cavity. Since in this alternative method anchor portion 32 is of the same material as the cantilever arm 34, and of a different material than the etchable layer 131, subsequent etching of the etchable layer 131 will release both the arm portion 32 and the cantilever portion 34 to provide cantilever 30.

As depicted in FIG. 2(b), a fluid channel template 140 is next formed along the longitudinal axis of cantilever 30. Fluid channel template 140 can be fabricated by depositing about 0.1 to 1 μm of sacrificial material followed by photoshaping and etching. Preferred materials for fluid channel template 140 include copper, aluminum and silicon dioxide.

Photoshaping is a well known technique for pattering layers, such as sacrificial or material layers. Typically, a polymeric photoresist material is deposited, for example by spin coating, over the layer to be patterned. The resist is masked and is then irradiated through the mask. The resist either polymerizes in the exposed areas (negative resist) or prevents polymerization in the areas exposed (positive resist). The non polymerized area of the resist is removed, e.g., in a developer solution, to provide the patterned resist. The exposed sacrificial or material layer can then be etched in the areas not covered by the resist to provide the desired pattern. The resist is then removed using an appropriate solution or etchant. Thus, fluid channel template 140 can be formed by depositing a sacrificial layer over cantilever 30, depositing a photoresist on the sacrificial layer, masking in a positive mask of the fluid channel template, irradiation, and removal of the unpolymerized resist. Etching of the exposed part of the sacrificial layer leaves fluid channel template 140. The photoresist is then removed.

A tip template 150 is next formed on cantilever 30 and fluid channel template 140, as shown in FIG. 2(c). Tip template 150 can be formed by depositing about 3 μm to about 10 μm cf a tip template layer material and then photoshaping and etching the layer into the tip template shape. Both isotropic and/or anisotropic etching may be used to yield tip template 150. Suitable tip template materials include, but are not limited to, metals such as copper and tantalum, nitrides such as silicon nitride, and carbides such as silicon carbide, and other materials such as silicon dioxide, or polyimide. Preferred tip template 150 materials include copper, aluminum and silicon dioxide. In an alternative embodiment, fluid channel template 140 and tip template 150 are formed together by depositing a single sacrificial material, such as copper, aluminum or silicon dioxide, onto cantilever 30, and photoshaping and etching the sacrificial material into the shape of the channel template and the tip template.

A shell layer 42 is next deposited over fluid channel template 140 and tip template 150, as depicted in FIG. 2(d). Shell layer 42 covers fluid channel template 140 and tip template 150 and forms the wall of these structures. Shell layer 42 can be formed by depositing about 1 μm to 5 μm, preferably 0.1-1 μm, of a shell layer material and photoshaping and etching the material as necessary. Suitable shell layer materials include but are not limited to, metals such as copper and tantalum, nitrides such as silicon nitride, and carbides such as silicon carbide, and other materials such as silicon dioxide, or polyimide.

An optional tip support layer 52 is next deposited over the portion of shell layer 42 covering tip template 150, and, optionally, over the end 152 of tip template 150, as depicted in FIG. 2(e). Tip support layer 52 provides additional structural support for the hollow tip 50. Tip support layer 52 is formed by depositing about 0.01 μm to about 1 μm of a support material, such as polycrystalline silicon, metals such as copper and tantalum, silicon nitride, silicon carbide, or other insulators, and photoshaping and etching the layer as necessary to provide the desired shape.

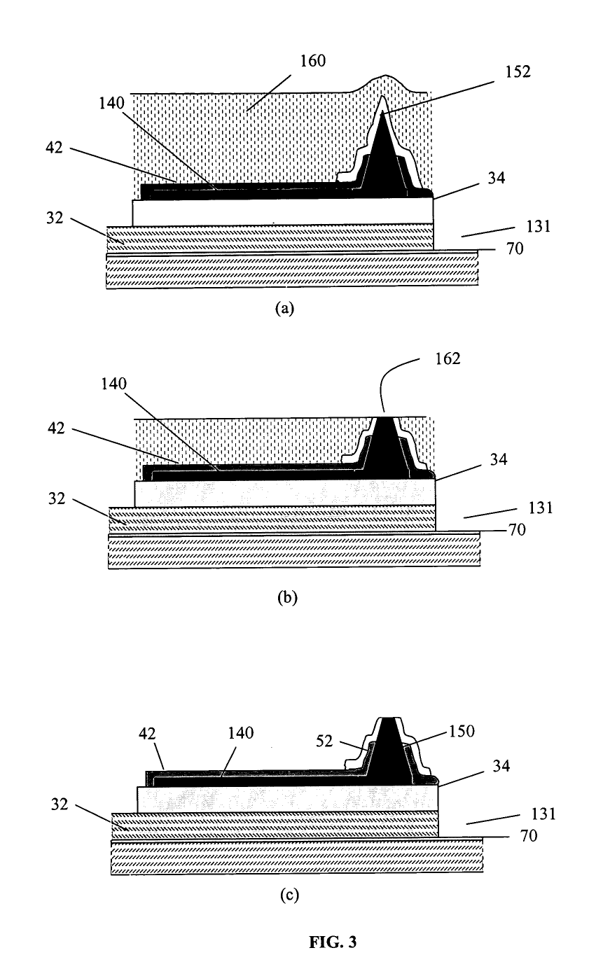

Tip template end 152, and any tip support layer 52 present thereon, are next removed, as depicted in FIG. 2(f). Removal of end 152 and materials deposited thereon is conducted by deposition of a CMP layer followed by planarization of the layer by CMP. This step is depicted in FIG. 3.

As shown in FIG. 3(a), a CMP layer 160 is deposited over shell layer 42, and end 152 of tip template 150. CMP layer 160 can be, for example, polycrystalline silicon, metals such as copper and tantalum, silicon nitride, or silicon carbide. The CMP layer 160 is then planarized by well known CMP planarization techniques, such that tip end 152, and any materials deposited thereon, are removed (FIG. 3(b)). The resultant opening 162 exposes tip template 150. CMP is conducted until opening 162 is of the desired diameter, which will depend on the final application. The remaining CMP layer 160 is then removed by etching (FIG. 3(c)). CMP processes and slurries for use in the invention are known in the art. See for example, U.S. Pat. Nos. 6,447,371, 6,432,828, 5,527,423, each of which is incorporated herein by reference.

Opening 62 can be fabricated in shell layer 42 by masking and etching. Tip template 150 and fluid flow channel template 140 are removed by etching. First etchable layer 131 is partially etched to provide anchor portion 32 of cantilever 30 (FIG. 2(g)).

Sacrificial and material layers used in the invention can be deposited or formed by various techniques well know in the art including spin-on coating, sputtering, e-beam evaporation, chemical vapor deposition (CVD), plasma assisted CVD, and spraying, and the like.

The etching processes used for removal of etchable and sacrificial layers is dependent on the material from which the layer is formed, as well as the desired resultant shape. Etchants and etching processes for removing etchable layers, including isotropic and anisotropic processes, are well known in the art. For instance, silicon dioxide can be removed by a wet etch process using hydrofluoric acid or by a dry plasma process using CF₄/O₂ gas. Polyimide can be removed by a wet etch using the manufacturer's recommended solution, or by dry etch in an oxygen plasma. Metals can be removed by dry or wet chemical methods. PMMA and other photoresist materials can be removed by dry or wet chemical methods. In the process of the invention, the etchable and sacrificial layers can be removed together or independently as discussed above.

No particular order is required for removing the etchable and sacrificial layers in the invention. A logical order for removing such layers can be readily determined by the person of ordinary skill in the art.

As discussed above, the process of the invention includes various material deposition steps, photoshaping steps and etching or partial etching steps. As will be understood by the person of skill in the art, the process of the invention can be optimized by the appropriate choice of materials, etching processes, and/or photoshaping techniques. Example combinations of materials are shown in Table 1. Components listed in the Table are as follows: A=protective layer 70; B=anchor portion 32; C=arm portion 34; D=fluid channel template 140; E=tip template 150; F=shell layer 42; G=support layer 52.

TABLE 1

| | Component | | | | | | |
|---|---|---|---|---|---|---|---|
| | A | B | C | D | E | F | G |
| Embodi- | SiC | SiO₂ | Poly Si | SiO₂ | SiO₂ | Poly Si | SiC |
| ment 1 | | | | | | | |
| materials | | | | | | | |
| Embodi- | SiC | SiO₂ | Poly Si | Cu | Cu | Poly- | Cr |
| ment 2 | | | | | | imide | |
| materials | | | | | | | |
| Embodi- | Si₃N₄ | SiO₂ | Si₃N₄ | Poly Si | Poly Si | SiO₂ | Ta, Cr, |
| ment 3 | | | | | | | or Cu |
| materials | | | | | | | |

In embodiment 1 of Table 1, components B, D, and E are of the same material (SiO₂), therefore conditions are preferably such that D and E are etched faster than B, in order that complete removal of B does not occur. In Embodiment 2, B, D and E are of different materials, therefore etchants that are selective to each material can be used.

It should be understood that the foregoing disclosure emphasizes certain specific embodiments of the invention and that all modifications or alternatives equivalent thereto are within the spirit and scope of the invention as set forth in the appended claims.

1. A method for fabricating a tip assembly for nanoscale fluid delivery, said method comprising:
forming on a substrate a cantilever supported on a first etchable layer;
forming on the cantilever a fluid channel template and a tip template having a tip end;
forming on the fluid channel template and the tip template a shell layer;
removing the tip end, the fluid channel template and the tip template; and
partially etching the first etchable layer to leave an anchor portion for the cantilever.

2. The method of claim 1 wherein said step of forming on a substrate a cantilever supported on a first etchable layer comprises depositing on the substrate the etchable layer and a cantilever material layer, and photoshaping and etching the cantilever material layer.

3. The method of claim 1 wherein said step of forming on the cantilever a fluid channel template and a tip template having a tip end comprises depositing onto the cantilever a second sacrificial material layer and photoshaping and etching the second sacrificial material.

4. The method of claim 1 wherein said step of forming on the fluid channel template and the tip template a shell layer comprises depositing a shell layer material on the cantilever and the fluid channel template and photoshaping and etching the shell layer material.

5. The method of claim 1 wherein said step of forming on the tip template and tip end a support layer comprises depositing a tip support material layer and photoshaping and etching the tip support material.

6. The method of claim 1 wherein removal of the tip end comprises depositing a CMP layer on the shell layer and planarizing the CMP layer to remove the tip end.

7. A tip assembly for nanoscale fluid delivery comprising:
a substrate;
a cantilever positioned on the substrate and having a fluid channel;
a hollow tip in fluid communication with the fluid channel and having an apical end for dispensing a fluid.

8. A tip array for nanoscale fluid delivery comprising:
a substrate;
a plurality of cantilevers positioned on the substrate and each having a fluid channel;
a plurality of hollow tips in fluid communication with the fluid channels.

9. The method of claim 1 wherein a support layer is formed on the tip template and tip end.

10. A tip assembly for nanoscale fluid delivery comprising:
a substrate;
a fluid channel on the substrate;
a shell layer enclosing the fluid channel; and
a hollow tip in fluid communication with the fluid channel.
